(19) United States
(12) Patent Application Publication
(10) Pub. No.: US 2026/0147970 A1
(43) Pub. Date: May 28, 2026

(54) Method and System for Physical-Aware Logic Synthesis

(71) Applicant: Mediatek Inc., Hsinchu City (TW)

(72) Inventors: Tai-Yu Cheng, Hsinchu City (TW); I-Lun Tseng, Hsinchu City (TW); Jian-Wei Lin, Hsinchu City (TW); Ming-Fang Tsai, Hsinchu City (TW); Wen-Chun Lan, Hsinchu City (TW)

(73) Assignee: Mediatek Inc., Hsinchu City (TW)

(21) Appl. No.: 19/383,773

(22) Filed: Nov. 10, 2025

Related U.S. Application Data
(60) Provisional application No. 63/725,037, filed on Nov. 26, 2024.

(51) Int. Cl. G06F 30/327

(52) U.S. Cl. CPC G06F 30/327

(57) ABSTRACT

Method and system are provided for performing physical-aware logic synthesis. A synthesis environment receives an RTL design, associated design constraints, and one or more design flow and physical design parameter settings. The RTL design is synthesized into a gate-level netlist while incorporating physical design considerations. A scoring result is computed from a logic synthesis result including the synthesized gate-level netlist to provide a quantitative measure of design quality. In certain aspects, the scoring result includes a scattering metric that evaluates placement density of standard cell instances, rankings across multiple modules, PPA results, and runtime prediction estimates. In further aspects, the design parameters are iteratively adjusted using artificial intelligence, reinforcement learning, or machine learning agents to optimize design quality. The invention enables improved integration of logical and physical design stages at advanced semiconductor process nodes.

### CROSS REFERENCE TO RELATED APPLICATIONS

This application claims the benefit of U.S. Provisional Application No. 63/725,037, filed on Nov. 26, 2024. The content of the application is incorporated herein by reference.

### BACKGROUND

As semiconductor technology advances into advanced process nodes such as 5 nm, 3 nm, and 2 nm, the design of system-on-chip (SoC) devices has become increasingly complex. Traditional design methodologies separate logic synthesis from physical design, relying on logic synthesis to generate a gate-level netlist from register-transfer level (RTL) code without sufficient knowledge of downstream layout constraints. However, physical effects such as wire delay, routing congestion, power grid structures, and macro placement have a significant impact on design performance, power consumption, and area efficiency.

This separation between logic synthesis and physical design can lead to inaccurate estimates of power, performance, and area (PPA) during early design stages. As a result, design teams often encounter serious issues late in the flow, including IR drop, hold-time violations, or excessive electronic design automation (EDA) flow runtimes. Addressing such issues late in the flow typically requires multiple iterations of placement, routing, and optimization, resulting in prolonged turnaround time and increased design cost.

Although efforts have been made to incorporate limited physical awareness into logic synthesis tools and logic synthesis flows, conventional approaches rely heavily on manual floorplanning or heuristic adjustments by expert engineers. Such methods lack automation, do not scale well to industrial-sized designs, and provide limited predictive accuracy of downstream physical effects. Moreover, existing flows do not adequately leverage modern machine learning techniques to explore parameter settings or predict runtime bottlenecks.

Accordingly, there is a need for improved methods and systems that integrate physical design parameters directly into logic synthesis, provide quantitative scoring of design quality at early stages, and enable automation through artificial intelligence, reinforcement learning, or machine learning techniques.

### SUMMARY

An embodiment provides a computer-implemented method for performing physical-aware logic synthesis. The method includes receiving a register-transfer level (RTL) design with associated design constraints, one or more design flow parameter settings, and one or more physical design parameter settings. The RTL design is synthesized into a gate-level netlist based on the received settings, and a scoring result is computed from the logic synthesis result (which includes the generated gate-level netlist) to provide a quantitative measure of design quality. An embodiment further provides a system for performing physical-aware logic synthesis. The system includes a memory for storing instructions and a processor for executing the instructions to receive the RTL design and settings, synthesize the design into a gate-level netlist, and compute scoring results that evaluate design quality.

In certain aspects, the design flow parameter settings include electronic design automation (EDA) tool and flow configurations. The physical design parameter settings may include a standard cell utilization rate, aspect ratio of the design's boundary, rectilinear shape specification, feed-through net information, channel dimensions, macro grouping definitions, macro guide constraints, power domain boundaries, a power/ground grid density, and/or port placement guide specifications. In some cases, synthesizing the RTL design includes performing circuit block macro placement based on these physical design parameter settings.

In certain aspects, the computed scoring result includes scattering metrics that evaluate placement density of standard cell instances. A scattering metric may be determined as a ratio of the average Euclidean distance of cell instances from a geometric center to a reference radius derived from the total cell area of a module in the design. The average coordinate center can be determined by averaging x- and y-coordinates of cell locations. The scattering metric may further be computed for a plurality of modules in the RTL design, and the scoring result can include a ranking of modules according to their respective scattering metrics.

In certain aspects, the method or system may also compute power, performance, and area (PPA) results and electronic design automation (EDA) tool runtime prediction results from the logic synthesis result (which includes a gate-level netlist). In other aspects, the design flow parameter settings and physical design parameter settings may be iteratively adjusted using an artificial intelligence (AI), reinforcement learning (RL), or machine learning (ML) agent based on the computed scoring results. Through such iterative optimizations, design quality may be improved by systematically balancing competing considerations of power, performance, and area efficiency.

To the accomplishment of the foregoing and related ends, certain embodiments comprise the features hereinafter fully described and particularly pointed out in the claims. The following description and accompanying drawings set forth in detail certain illustrative aspects of the embodiments. These aspects are indicative, however, of but a few of the various ways in which the principles of the embodiments may be employed, and the present disclosure is intended to include all such aspects and their equivalents. These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a conventional integrated circuit design flow showing the separation of logic synthesis and physical synthesis in the prior art.

FIG. 2 illustrates a system for performing physical-aware logic synthesis according to an embodiment.

FIG. 3 illustrates a method for computing a scattering score for standard cell instances according to an embodiment.

FIG. 4 illustrates a geometric representation of the scattering score computation described in FIG. 3.

FIG. 5 illustrates a reinforcement learning framework integrated with the physical-aware logic synthesis system according to an embodiment.

FIG. 6 illustrates a flow diagram of a method for building runtime prediction models using machine learning techniques according to an embodiment.

FIG. 7 illustrates a flow diagram of a method for performing physical-aware logic synthesis according to an embodiment.

### DETAILED DESCRIPTION

While specific implementation details are presented herein to facilitate a comprehensive understanding of the disclosure, it will be apparent to those skilled in the art that the present invention may be realized without necessarily adhering to all such particularities. In certain instances, well-established methods, procedures, components, and circuits have been omitted from exhaustive description to avoid obscuring the present disclosure. It should be understood that technical features individually described in relation to a single drawing may be implemented either discretely or in combination with other features, as set forth in the present specification.

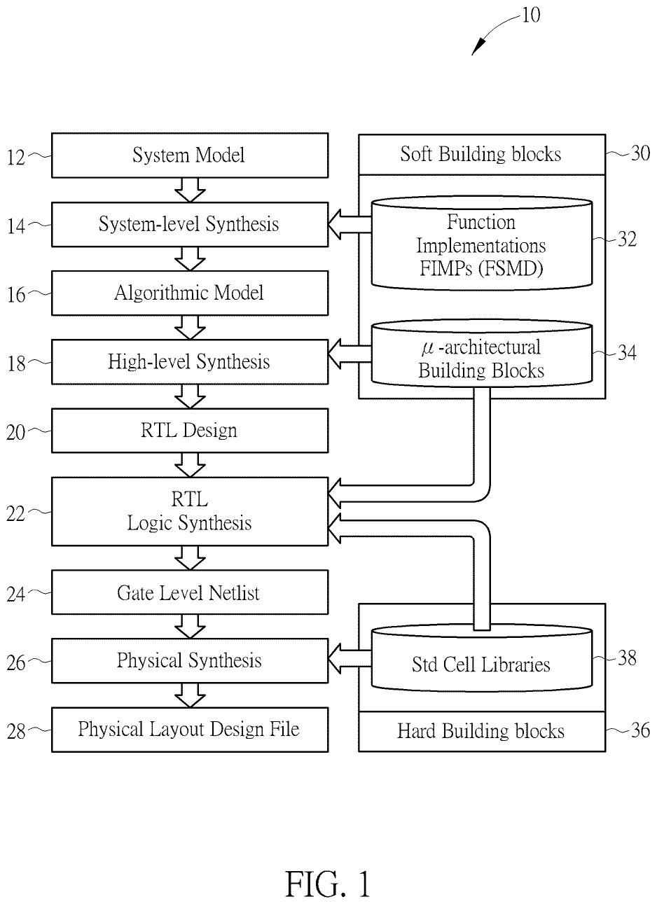

FIG. 1 illustrates a integrated circuit design flow 10 showing the progression from high-level system specifications to final physical layout according to the prior art. The design flow 10 demonstrates the traditional hierarchical approach to chip design and highlights where different types of building blocks are incorporated at various abstraction levels.

The design flow 10 begins at the highest level of abstraction with a system model 12, which defines the overall functionality and performance requirements of the integrated circuit. The system model 12 may specify system-level behaviors, interfaces, and performance targets without detailing implementation specifics.

From the system model 12, the flow proceeds to system-level synthesis 14, which translates high-level system specifications into algorithmic descriptions. The system-level synthesis 14 may partition functionality across multiple processing elements and define data flow patterns. At this stage, soft building blocks 30 may be utilized. Soft building blocks 30 include function implementations and finite state machines with data path (FIMPs/FSMD) 32, which represent reusable algorithmic components that can be instantiated and configured according to design requirements. These soft blocks are flexible and technology-independent at this stage.

The algorithmic model 16 represents the design as a collection of algorithms and computational structures. The algorithmic model 16 defines operations and their sequencing without committing to specific hardware implementations.

High-level synthesis 18 transforms the algorithmic model 16 into a register-transfer level representation. During high-level synthesis 18,μ-architectural building blocks 34 from the soft building blocks 30 may be incorporated. These micro-architectural building blocks 34 represent parameterizable hardware structures such as arithmetic units, controllers, and memory interfaces that can be customized during synthesis.

The RTL design 20 provides a description of the circuit behavior, specifying operations that occur on each clock cycle and defining registers, combinational logic, and control flow. The RTL design 20 typically comprises hardware description language code such as Verilog or VHDL.

RTL logic synthesis 22 converts the RTL design 20 into a gate-level representation using standard cell libraries. The RTL logic synthesis 22 receives inputs from multiple sources. Function implementations from the soft building blocks 30 may provide pre-designed RTL modules that are incorporated into the design. Micro-architectural building blocks 34 supply architectural templates that guide synthesis decisions. Standard cell libraries 38 provide the technology-specific logic gates, flip-flops, and other basic circuit elements used to implement the RTL functionality.

The gate-level netlist 24 represents the circuit as an interconnection of standard cell instances from the target technology libraries. The netlist 24 specifies logic gates, sequential elements, macros, and their connectivity, but does not yet contain physical placement or physical routing information.

Physical synthesis 26 transforms the gate-level netlist 24 into a physical layout by placing macros and standard cell instances at specific locations and by adding routing interconnections between them. Physical synthesis 26 utilizes standard cell libraries 38, which provide physical layout and other information including cell dimensions, pin locations, timing characteristics, and power characteristics. Physical synthesis 26 also incorporates hard building blocks 36, which include pre-designed macros with fixed physical layouts such as memory arrays, analog blocks, or other IP blocks that cannot be synthesized from RTL.

The final output is a physical layout design file 28, which represents the complete physical layout suitable for mask generation and fabrication. The physical layout design file 28 may be provided in industry-standard formats such as GDSII (Graphic Design System II) format, OASIS (Open Artwork System Interchange Standard) format or other file formats suitable for mask generation and fabrication. The physical layout design file 28 includes geometric shapes defining the physical structures of the integrated circuit, layer assignments specifying which manufacturing layers each geometric element belongs to, and manufacturing data required to produce the integrated circuit including mask generation information, design rule specifications, and hierarchical design information.

FIG. 1 illustrates the separation between logic synthesis (RTL logic synthesis 22) and physical synthesis (physical synthesis 26), wherein logic synthesis generates a netlist without considering physical layout effects, and physical considerations are deferred until the physical synthesis stage. This separation can lead to challenges at advanced process nodes where physical effects such as wire delay, routing congestion, and power distribution significantly impact circuit performance. The present invention addresses these limitations by integrating physical awareness into the logic synthesis phase as described in the following paragraphs.

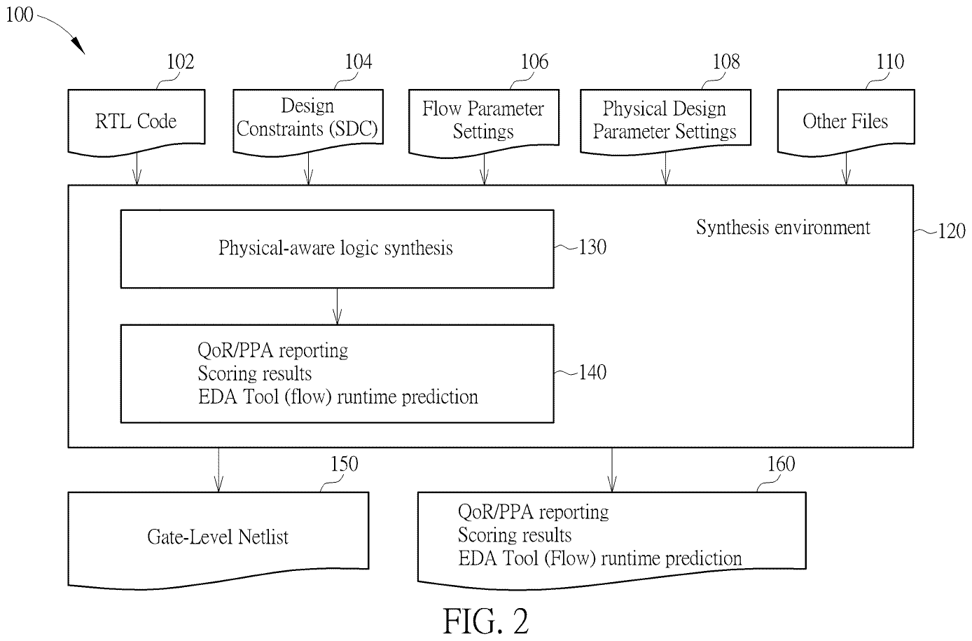

FIG. 2 illustrates a system 100 for performing physical-aware logic synthesis according to an embodiment. The system 100 includes a synthesis environment 120 that receives multiple categories of input data, processes the data through integrated synthesis and analysis modules, and generates output artifacts including a gate-level netlist and comprehensive evaluation results.

The synthesis environment 120 can receive five distinct types of input data. RTL code 102 includes register-transfer level hardware description code, typically expressed in hardware description languages such as Verilog or VHDL, representing the functional behavior of the integrated circuit design. Design constraints 104, which may be provided in Synopsys Design Constraints (SDC) format, specify timing requirements, clock definitions, input/output delay constraints, and other design rules that must be used or satisfied during logic synthesis. Flow parameter settings 106 define electronic design automation (EDA) tool configurations and synthesis flow options that control the behavior of the logic synthesis process. In some embodiments, the flow parameter settings 106 may include optimization strategies, effort levels, and tool-specific options. Physical design parameter settings 108 specify physical implementation characteristics. These settings may include one or more of standard cell utilization rates, aspect ratios, floorplan geometry (rectangular or rectilinear), feed-through port numbers and locations, macro grouping preferences, channel dimensions between macros, power domain boundaries, power/ground grid density specifications, and port placement guides. Other files 110 may include additional supporting data such as Unified Power Format (UPF) files for power intent specification, technology library files, physical library files, and process-specific design rules.

To avoid ambiguity, this specification uses the term “module” in two distinct contexts: (1) system modules such as the logic synthesis module and analysis and reporting module, which are functional components of the synthesis tool; and (2) design modules (also referred to as an RTL module, circuit module, or hierarchical module), which are hierarchical units within the RTL code being processed. The context will make clear which meaning applies.

Within the synthesis environment 120, a physical-aware logic synthesis module 130 can perform the core synthesis operations. This physical-aware logic synthesis module 130 integrates commercial logic synthesis tools with proprietary macro placement functionality to generate technology-mapped gate-level netlists while simultaneously accounting for physical layout effects. The physical-aware logic synthesis module 130 may perform automatic macro placement, generate power domain region definitions, and insert power/ground grid structures during the synthesis phase, thereby incorporating physical design considerations that are traditionally deferred to later design stages. The synthesis module 130 processes the RTL code 102 according to the design constraints 104, flow parameter settings 106, and physical design parameter settings 108 to produce an optimized circuit implementation.

An analysis and reporting module 140 can execute multiple jobs or tasks to evaluate the quality of the synthesized design. A first task performs Quality of Results (QoR) and Power, Performance, and Area (PPA) reporting, generating comprehensive metrics. These metrics may include power consumption analysis (both static and dynamic components), performance metrics such as worst negative slack (WNS) and total negative slack (TNS), and area measurements including total cell area and utilization rates.

A second task computes scoring results based on evaluation methodologies. This scoring may include calculation of scattering metrics for standard cell instances within each module of a circuit design/block, wherein a scattering metric represents a normalized measure of the cell placement density for a module or a circuit block.

In this context, the module (meaning RTL module, design module or hierarchical module) refers to a logical design unit defined in the RTL code 102, typically representing a reusable functional component such as an arithmetic logic unit, memory controller, interface block, or other logical partition of the design hierarchy. Modules are organized hierarchically in the RTL code, where higher-level modules may instantiate lower-level modules to build complex functionality. Each module is defined once in the RTL code but may be instantiated multiple times within the overall circuit. A circuit block, on the other hand, typically refers to a physical partition of an integrated circuit that may contain multiple module instances along with macros, power distribution structures, and routing resources.

In certain embodiments, a scattering metric may be computed as a ratio of an average Euclidean distance from cell instances to a center point of a module or a circuit block, divided by a reference radius derived from total cell area. The scoring results may further include risk assessments for IR drop susceptibility, hold-time violation removal difficulty, static and dynamic power consumption issues, and routing congestion hotspots. A third task may perform EDA tool and flow runtime prediction using machine learning models to estimate the turnaround time required for completing the full design flow from RTL to final layout, enabling identification of parameter combinations that may result in excessive design cycle duration.

The synthesis environment 120 can produce two primary categories of output. A gate-level netlist 150 includes the technology-mapped circuit representation including standard cells, macros, and interconnections. The netlist 150 represents the transformation of the input RTL code 102 into actual circuit components from the target process technology library, with optimizations applied based on both logical functionality and physical implementation constraints. A results artifact 160 includes output files generated by the analysis and reporting module 140. The results artifact 160 may include detailed QoR/PPA reports, computed scoring results with per-module or per-block scattering metrics and risk classifications, runtime prediction estimates, floorplan visualization data showing macro positions and power domain configurations, and comparative analysis data relative to baseline designs or previous iterations.

In some embodiments, the physical-aware logic synthesis process includes automatic placement of macros based on the physical design parameter settings. The macros may include memory macros such as SRAM macros, ROM macros, and register file macros, as well as other hard intellectual property (IP) blocks such as analog/digital/mixed-signal blocks, interface blocks, or custom accelerator blocks. The automatic macro placement may be performed by a macro placement process integrated within the physical-aware logic synthesis module 130. The macro placement process receives the RTL design, design constraints, and physical design parameter settings as inputs and generates placement coordinates and orientations for macros within the circuit block floorplan.

The physical design parameter settings that control the automatic macro placement process may include various adjustable parameters. A standard cell utilization rate parameter specifies the target density for standard cell instance placement, typically expressed as a percentage of available placement area. An aspect ratio parameter defines the height-to-width ratio of the circuit block boundary, enabling exploration of different floorplan proportions. A rectilinear shape specification parameter enables definition of non-rectangular circuit block boundaries comprising multiple rectangular regions, which may be advantageous for fitting complex chip-level floorplan requirements.

Feed-through net parameters specify the numbers and preferred locations of routing paths that traverse through the entire circuit block or design, enabling connectivity between different regions of the circuit block/design. Channel dimension parameters define minimum or preferred spacing between adjacent macros, which may influence routing congestion and power distribution characteristics. Macro grouping definition parameters specify logical associations or clustering preferences for multiple macros that should be placed in proximity to each other, which may be based on functional relationships, connectivity patterns, or power domains. Macro guide constraint parameters define preferred regions, locations, or orientations for individual macros or macro groups, enabling designer input to influence the automated placement process.

A power domain boundary parameter specifies how power domain regions should be arranged within the circuit block/design. The parameter may specify center placement wherein a default voltage domain is positioned centrally with other domains surrounding it, edge placement wherein power domains are arranged along circuit block edges, or ring placement wherein one domain surrounds another in a concentric configuration. A power-ground grid density parameter specifies the spacing or pitch of power distribution network elements such as power stripes or mesh structures, which affects IR drop characteristics and routing resources. Port placement guide specifications define preferred locations for input/output ports along the circuit block/design boundary, which may be determined automatically based on connectivity to adjacent blocks or specified according to designer preferences.

The architecture illustrated in FIG. 2 enables an integrated approach to logic synthesis wherein physical design considerations are incorporated during the synthesis phase rather than being addressed in subsequent design stages. The scoring results generated by the analysis and reporting module 140 provide quantitative measures of design quality that can be utilized to guide iterative optimization of the flow parameter settings 106 and physical design parameter settings 108. In some embodiments, this optimization may be performed through manual designer intervention. In other embodiments, the optimization may be performed through automated techniques using artificial intelligence, reinforcement learning, or machine learning agents as described in other aspects of the present invention.

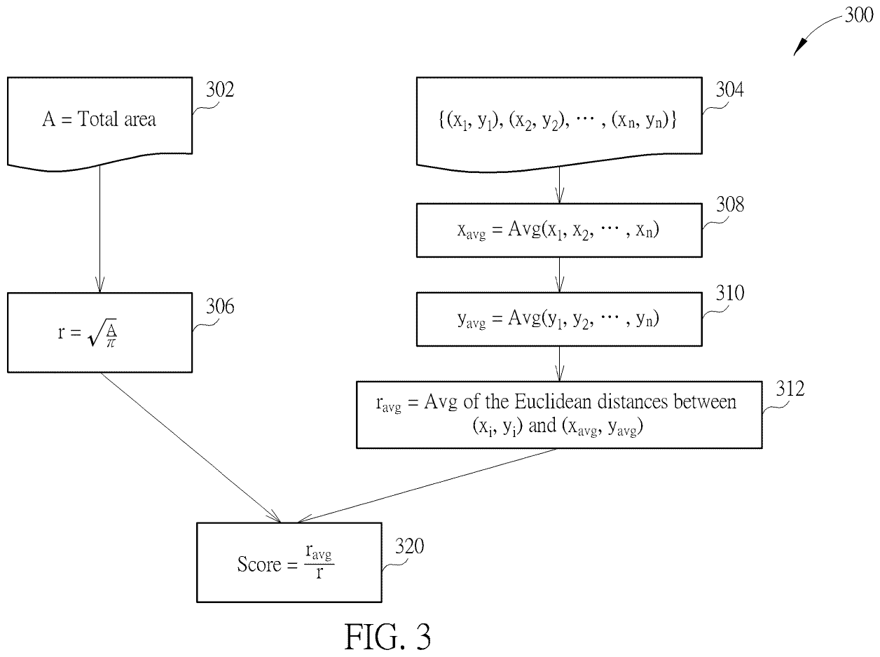

FIG. 3 illustrates a method 300 for computing a scattering score for standard cell instances according to an embodiment. The method 300, performed by the analysis and reporting module 140 within the synthesis environment 120 of FIG. 2, provides a quantitative metric for evaluating the spatial distribution density of cell instances.

The method 300 receives two input parameters. An input parameter 302 represents a total area A corresponding to the sum of all standard cell instance areas within a module or a circuit block being evaluated. Note that a circuit block or a circuit design can have multiple modules (e.g., tens of thousands of modules). A second input parameter 304 includes a set of coordinate pairs (x₁, y₁), (x₂, y₂), . . . , (xₙ, yₙ) representing the physical locations of n standard cell instances within the module or the circuit block, where each coordinate pair (xᵢ, yᵢ) specifies the planar position of the i-th cell instance (e.g., for the cell instance's lower-left corner).

At operation 306, a reference radius r is computed from the total area A according to the formula r=\sqrt{(A/π)}. The reference radius r represents the radius of a circle having area equal to A, corresponding to an idealized dense packing configuration. The reference radius r serves as a normalization factor for subsequent comparison with actual cell distribution characteristics.

At operation 308, an average x-coordinate x_{avg} is computed as the arithmetic mean of all x-coordinates in the input set: x_{avg}=Avg(x₁, x₂, . . . , xₙ). The average x-coordinate x_{avg} represents the horizontal component of the geometric centroid of the cell instances.

At operation 310, an average y-coordinate y_{avg} is computed as the arithmetic mean of all y-coordinates in the input set: y_{avg}=Avg(y₁, y₂, . . . , yₙ) . The average y-coordinate y_{avg} represents the vertical component of the geometric centroid of the cell instances. Together, the coordinate pair (x_{avg}, y_{avg}) defines a center point representing the spatial center of the cell instances of the module or the circuit block.

Note that the sequence of operation 308 and operation 310 are interchangeable. Also, these two operations may be executed in parallel.

At operation 312, an average distance r_{avg} is computed. The average distance r_{avg} is calculated as the mean of all Euclidean distances between each individual cell instance location (xᵢ, yᵢ) and the center point (x_{avg}, y_{avg}). For each cell instance i, the Euclidean distance may be computed as \sqrt{(xᵢ−x_{avg})²+(yᵢ−y_{avg})²}, and r_{avg} is obtained by averaging these n distance values. The average distance r_{avg} quantifies the actual spatial dispersion of cell instances from their geometric center.

At operation 320, a score is computed as the ratioscore=r_{avg}/r. The score compares the actual average dispersion r_{avg} to the reference radius r, providing a normalized metric of the cell placement density for a module or a circuit block. The score value is independent of the absolute number or total area of cell instances, enabling comparison across circuit blocks/designs of different sizes.

The computed score may be interpreted to assess design risks. A score value lower than or approximately equal to 1.0 may indicate that cell instances are clustered tightly, which may correlate with increased IR drop risk when multiple high-activity cells switch simultaneously and may present challenges for hold-time violation removal due to limited space for buffer insertion. A score value substantially greater than 1.0 may indicate that cell instances are more dispersed than the idealized configuration, which may correlate with increased power consumption due to longer interconnect paths requiring additional buffering elements.

In some embodiments, the method 300 may be applied to a plurality of modules or circuit blocks within the integrated circuit design. For each module or circuit block, operations 302 through 320 may be executed to generate a corresponding score. The resulting collection of scores may be utilized in various ways. The scores may be aggregated to compute statistical measures such as mean, median, maximum, or minimum scores across different modules or circuit blocks. The modules or circuit blocks may be ranked according to their scores to identify circuit designs exhibiting extreme clustering or dispersion characteristics. Modules or circuit blocks having scores exceeding predetermined threshold values may be flagged for further analysis or design optimization. The scores may be weighted according to circuit blocks characteristics such as switching activity, power consumption, or timing criticality before aggregation or ranking. The per-module or per-block scores may be incorporated into the results artifact 160 as described in FIG. 2, enabling designers to identify blocks requiring attention during subsequent design refinement iterations.

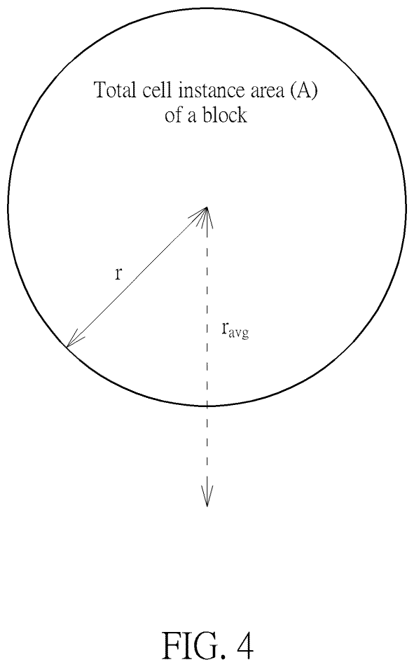

FIG. 4 illustrates a geometric representation of the scattering score computation described in FIG. 3, providing a visual explanation of the spatial relationships between parameters used in the method 300 according to an embodiment.

The figure depicts a circle representing an idealized dense packing configuration for standard cell instances within a module or circuit block. The circle has a total area A, which corresponds to the total cell instance area 302 described in FIG. 3. The area A represents the sum of all individual standard cell instance areas within the module or circuit block being evaluated.

A reference radius r is shown as the radius of the circle, extending from the center of the circle to its perimeter. The reference radius r is computed according to the formulaᵣ=\sqrt{(A/π)} as described in operation 306 of FIG. 3. This radius represents the theoretical minimum radius required to contain all cell instances if they were packed into a perfectly circular region with no wasted space. The reference radius r serves as a baseline for comparing actual cell distribution patterns against an idealized dense configuration.

The average distance r_{avg} is illustrated by the dashed arrow extending vertically downward from the center point. The average distance r_{avg} represents the mean of all Euclidean distances between individual cell instance locations and the center point. Thus, the average distance r_{avg} quantifies how dispersed the cell instances are from their geometric center in the actual placement configuration.

The circular representation in FIG. 4 provides a visualization for placement density. A tightly clustered placement would show r_{avg} as a relatively short distance compared to r, while a dispersed placement would show r_{avg} approaching or exceeding r. This geometric interpretation facilitates understanding of how the scattering score relates to physical placement characteristics and associated design risks such as IR drop susceptibility, hold-time violation challenges, and power consumption implications as described in connection with FIG. 3. While individual cell instances would be located at various positions throughout the circular region, the key metric is the average distance from these positions to the central reference point compared to the radius of the dense circle. This normalized comparison enables fair assessment of placement density across modules or circuit blocks of different sizes and cell counts.

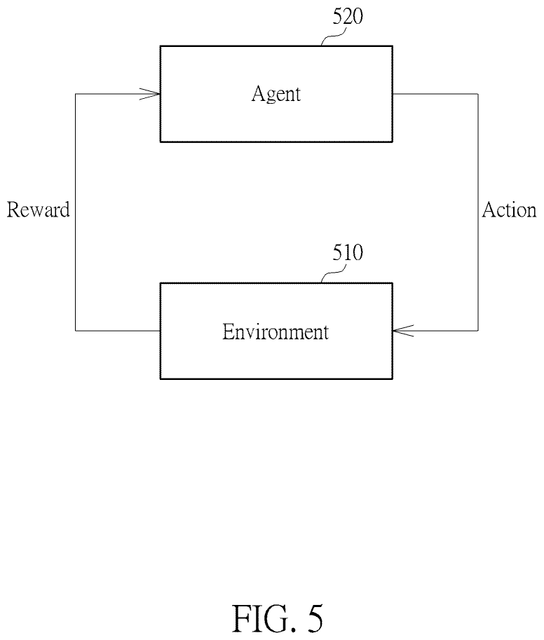

FIG. 5 illustrates a reinforcement learning framework that can be integrated with the physical-aware logic synthesis system according to an embodiment. The framework includes an agent 520 and an environment 510 that interact through a feedback loop to iteratively optimize design parameters.

The agent 520 can be an artificial intelligence (AI) agent, machine learning (ML) agent, or reinforcement learning (RL) agent configured to automatically explore and optimize design parameters. The agent 520 may implement various reinforcement learning algorithms such as Q-learning, policy gradient methods, actor-critic methods, deep reinforcement learning techniques, or other suitable machine learning approaches. The agent 520 operates according to reinforcement learning principles wherein the agent learns to make decisions by observing the consequences of its actions in the environment and adjusting its behavior to maximize cumulative rewards over time.

The environment 510 corresponds to the synthesis environment 120 described in FIG. 2 and includes, e.g., the physical-aware logic synthesis module 130 and analysis and reporting module 140. The environment 510 receives input data including RTL code, design constraints, flow parameter settings, and physical design parameter settings as previously described. The environment 510 processes this input data to perform physical-aware logic synthesis operations and generates outputs including gate-level netlists and comprehensive evaluation results.

The framework operates through an iterative feedback loop. The agent 520 generates an action that modifies one or more design parameters. The action may include adjustments to flow parameter settings 106 and physical design parameter settings 108 as described in FIG. 2. These actions may specify changes to standard cell utilization rates, aspect ratios, feed-through configurations, power grid densities, or other parameters that influence the synthesis process. In some embodiments, the agent 520 may represent the action as a vector or set of values corresponding to specific parameter modifications.

The environment 510 receives the action from the agent 520 and executes the physical-aware logic synthesis process using the modified parameters. The environment 510 generates output artifacts and evaluation metrics based on the synthesis results. These outputs may include QoR/PPA reports, scoring results with scattering metrics, runtime predictions, and other quantitative measures of design quality as described in connection with FIG. 2.

The environment 510 computes a reward signal based on the output artifacts and evaluation metrics. The reward signal provides quantitative feedback to the agent 520 indicating the quality of the design produced using the parameters specified in the action. The reward may be computed as a function of multiple factors including power consumption, performance metrics such as timing slack values, area utilization values, scattering scores, predicted runtimes, and other relevant design quality indicators. In some embodiments, the reward function may apply weights to different factors based on design priorities or constraints. The reward signal may be a scalar value or a multi-dimensional vector representing different aspects of design quality.

The reward signal is transmitted from the environment 510 back to the agent 520, completing the feedback loop. The agent 520 uses the reward signal to update its internal decision-making policy or model according to reinforcement learning principles. The agent 520 learns to associate certain parameter configurations with higher or lower rewards, enabling it to generate improved actions in subsequent iterations. The agent 520 may maintain a policy network, value function, or other learned model that maps observed states to preferred actions.

Through repeated iterations of this feedback loop, the agent 520 progressively learns to identify parameter configurations that yield improved design quality metrics. The iterative optimization process enables automated exploration of the design space without requiring manual intervention to specify each parameter combination. The framework can discover non-obvious parameter interactions and identify optimal or near-optimal design configurations that may be difficult to determine through manual exploration alone.

In some embodiments, the agent 520 may maintain historical data regarding previous actions and their corresponding rewards, enabling the agent to build a comprehensive understanding of the relationship between design parameters and resulting design quality. The agent 520 may balance exploration of new parameter combinations with exploitation of known high-performing configurations to efficiently navigate the design space. The agent 520 may employ epsilon-greedy strategies, upper confidence bound methods, or other exploration-exploitation techniques to optimize learning efficiency.

In some embodiments, the automatic macro placement process utilizes these physical design parameter settings to generate a floorplan configuration that satisfies design constraints while optimizing for metrics such as wire length, timing performance, routing congestion, and power consumption. The flexibility provided by the adjustable parameters enables exploration of different floorplan alternatives during iterative design optimization.

The reinforcement learning framework provides an automated mechanism for design space exploration and optimization, reducing the manual effort required to achieve high-quality physical-aware logic synthesis results while systematically addressing challenges related to power, performance, area, and design cycle time.

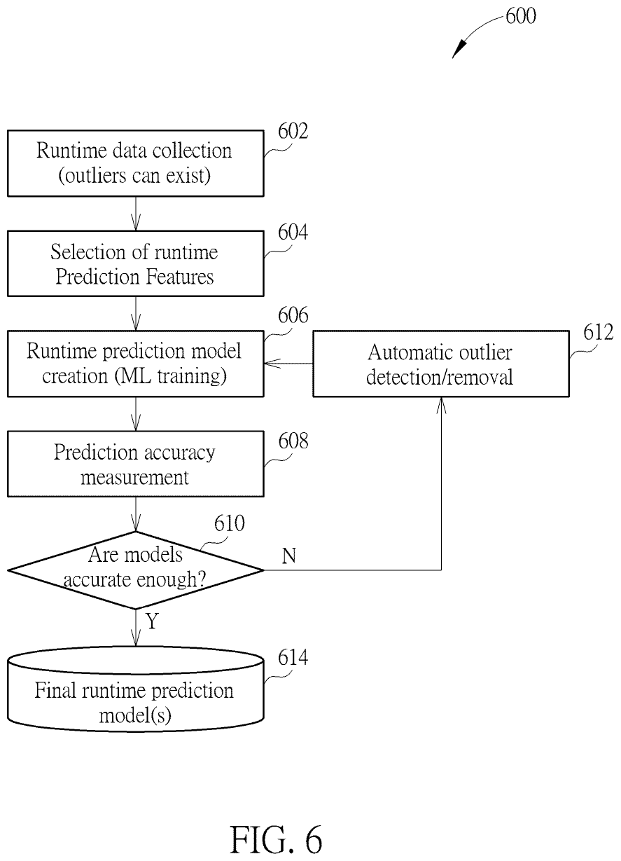

FIG. 6 illustrates a flow diagram of a method 600 for building runtime prediction models using machine learning techniques according to an embodiment. The method 600 addresses the challenges of predicting EDA tool and flow execution times, which may be incorporated into the analysis and reporting module 140 of FIG. 2 to generate runtime prediction estimates as part of the results artifact 160.

The method 600 begins at step 602 with runtime data collection. Historical runtime data is collected from previous executions of the EDA tool flow or physical-aware logic synthesis process. The collected data may include actual execution times for various design configurations along with associated design characteristics such as cell instance counts, net counts, macro counts, design complexity metrics, and parameter settings used during synthesis. The collected runtime data may contain outliers, which are data points that deviate significantly from typical values due to incorrect settings, measurement errors, abnormal system conditions, or atypical design characteristics.

At step 604, selection of runtime prediction features is performed. Feature selection identifies which design characteristics and parameters are most predictive of runtime behavior. The selected features may include metrics extracted from the RTL design such as module counts, instance counts, hierarchical depth, and connectivity complexity. The features may also include parameters from the design flow settings and physical design parameter settings. Feature selection techniques such as correlation analysis, mutual information, or recursive feature elimination may be employed to identify the most relevant predictors while reducing dimensionality.

At step 606, runtime prediction model creation is performed using machine learning training techniques. One or more prediction models are trained using the collected runtime data and selected features. The machine learning techniques may include regression methods such as linear regression, polynomial regression, or support vector regression. Alternatively, tree-based methods such as decision trees, random forests, or gradient boosting machines may be employed. Neural network architectures including deep learning models may also be utilized. The training process adjusts model parameters to minimize prediction error on the training dataset.

At step 612, automatic outlier detection and removal is performed. An outlier detection module analyzes the training data to identify data points that significantly deviate from expected patterns. Outlier detection techniques may include statistical methods such as z-score analysis, interquartile range analysis, or isolation forests. Machine learning-based anomaly detection approaches may also be employed. Detected outliers are removed from the training dataset to prevent them from degrading model accuracy. The cleaned dataset is then provided back to step 606 for model retraining.

At step 608, prediction accuracy measurement is performed. The trained model's performance is evaluated using validation techniques such as cross-validation or holdout validation. Accuracy metrics may include mean absolute error, root mean square error, mean absolute percentage error, Pearson correlation coefficient (PCC), or R-squared values. The prediction accuracy is assessed by comparing predicted runtimes against actual measured runtimes for designs not used during training.

At step 610, a determination is made whether the models are accurate enough. Predetermined accuracy thresholds or acceptance criteria are applied to determine if the model performance is sufficient for practical use. The accuracy requirements may depend on the intended application and the acceptable margin of error for runtime estimates. If the models are determined to be accurate enough, the method proceeds to step 614. If the models are not accurate enough, the method returns to step 612 for additional outlier detection and removal, followed by retraining at step 606.

The iterative loop comprising steps 606, 608, 610, and 612 continues until satisfactory model accuracy is achieved. This iterative refinement process progressively improves model quality by identifying and removing problematic training data and retraining with cleaner datasets.

At step 614, final runtime prediction models are produced and stored. The final models represent the trained machine learning models that have achieved acceptable prediction accuracy. The models may be stored in a format suitable for deployment within the synthesis environment 120. Multiple models may be generated for different stages of the design flow or different types of designs. The final runtime prediction models can be utilized during physical-aware logic synthesis to estimate expected execution times for different parameter configurations, enabling the agent 520 in FIG. 5 to avoid parameter combinations that would result in excessive design cycle duration.

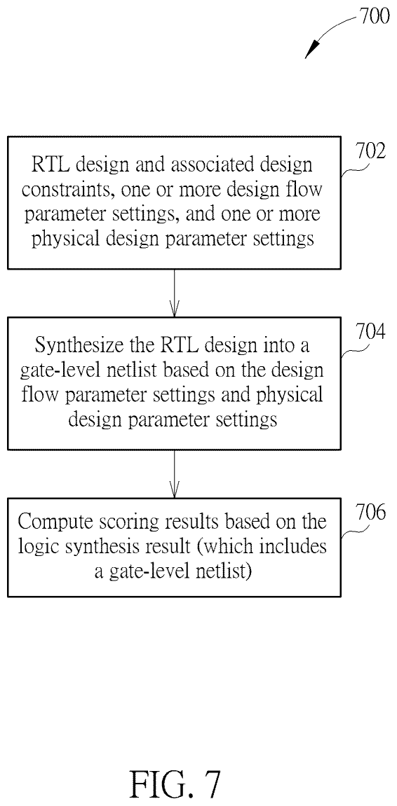

FIG. 7 illustrates a flow diagram of a method 700 for performing physical-aware logic synthesis according to an embodiment. The method 700 may be implemented by a computer system executing the synthesis environment 120 described in FIG. 2 and represents a high-level overview of the physical-aware logic synthesis process. The method 700 includes the following steps:
702: Receive an RTL design and associated design constraints, one or more design flow parameter settings, and one or more physical design parameter settings;
704: Synthesize the RTL design into a gate-level netlist based on the design flow parameter settings and physical design parameter settings; and
706: Compute scoring results based on the logic synthesis result (which includes a gate-level netlist).

At step 702, a register-transfer level (RTL) design and associated design constraints are received, along with one or more design flow parameter settings and one or more physical design parameter settings. The RTL design may be provided as hardware description language code such as Verilog or VHDL that specifies the functional behavior of the integrated circuit at the register-transfer abstraction level. The associated design constraints may be provided in standard formats such as Synopsys Design Constraints (SDC) files, which specify timing requirements including clock definitions, clock periods, input and output delay constraints, false path declarations, and multicycle path specifications. The design constraints may also include area constraints, power constraints, or other optimization objectives.

The design flow parameter settings received at step 702 correspond to the flow parameter settings 106 described in FIG. 2. These settings may include electronic design automation (EDA) tool configuration parameters that control the behavior of the logic synthesis process. The design flow parameter settings may specify optimization strategies such as area-focused optimization, timing-focused optimization, or balanced optimization approaches. The settings may define effort levels that control how extensively the synthesis tool explores different implementation alternatives. The settings may also include parameters for technology mapping strategies, logic restructuring options, arithmetic optimization techniques, and other tool-specific configuration options.

The physical design parameter settings received at step 702 correspond to the physical design parameter settings 108 described in FIG. 2. These settings may include parameters that influence the physical implementation of the circuit and enable physical-aware synthesis. The physical design parameter settings may specify a standard cell utilization rate that defines the target density for standard cell placement within the circuit block. An aspect ratio parameter may define the height-to-width ratio of the circuit block boundary. A rectilinear shape specification may define non-rectangular circuit block geometries. The settings may include feed-through net specifications defining routing paths that traverse through or between circuit blocks, channel dimension specifications defining spacing between adjacent macros, and macro grouping definitions specifying logical associations between multiple macros. Macro guide constraints may define preferred placement regions or locations for individual macros or macro groups. A power domain boundary parameter may specify arrangements such as center placement, edge placement, or ring placement configurations. A power-ground grid density specification may define the spacing of power distribution network elements. Port placement guide specifications may define preferred locations for input/output ports along the circuit block boundary.

At step 704, the RTL design is synthesized into a gate-level netlist based on the design flow parameter settings and the physical design parameter settings. The synthesis process may be performed by the physical-aware logic synthesis module 130 described in FIG. 2. The synthesis process transforms the behavioral RTL description into a structural gate-level representation using standard cells from a target technology library.

The synthesis at step 704 may include multiple sub-operations. A first sub-operation may perform elaboration and generic synthesis, wherein the RTL code is parsed, elaborated into an internal representation, and transformed into technology-independent logic. Boolean optimization techniques may be applied to minimize logic complexity. A second sub-operation may perform technology mapping, wherein the technology-independent logic is mapped to specific standard cells from the target library. The technology mapping may consider timing, area, and power objectives specified in the design flow parameter settings. A third sub-operation may perform automatic macro placement based on the physical design parameter settings. The macro placement determines physical locations and orientations for hard IP blocks such as memory macros within the circuit block floorplan. The macro placement may consider the physical design parameter settings including utilization rates, aspect ratios, channel dimensions, macro groupings, macro guides, and other placement constraints as described in claim 9. A fourth sub-operation may generate power domain region definitions based on the power domain boundary parameters, defining the spatial arrangement of different voltage domains within the circuit block. A fifth sub-operation may insert power/ground grid structures based on the power-ground grid density specification, establishing the power distribution network topology.

The synthesis process at step 704 integrates physical design considerations during logic synthesis rather than deferring them to subsequent design stages. This physical-aware approach enables the synthesis tool to make implementation decisions that account for physical layout effects such as wire delays, routing congestion, and power distribution characteristics. The synthesis result includes not only a gate-level netlist (which describes the logical connectivity between standard cells and macros) but also preliminary physical information such as macro placements and power grid structures that can be used to guide subsequent physical design operations.

At step 706, a scoring result is computed based on the logic synthesis result (which includes the gate-level netlist). The scoring result provides quantitative metrics that evaluate the quality and characteristics of the synthesized design. The computation of scoring results may be performed by the analysis and reporting module 140 described in FIG. 2.

The scoring result computed at step 706 may include multiple components. A first component may include scattering metrics that evaluate the placement density of standard cell instances within modules of the design or the entire circuit block/design. The scattering metrics may be computed using method 300 illustrated in FIG. 3, wherein for each module or the entire circuit block/design, a score is calculated as the ratio of an average Euclidean distance of cell instances from their geometric center to a reference radius derived from total cell area. A scattering metric provides an indication of whether cell instances are tightly clustered or spatially dispersed, which correlates with design risks such as IR drop susceptibility, hold-time violation challenges, and power consumption characteristics as described in connection with FIGS. 3 and 4.

A second component of the scoring result may include risk assessment metrics that identify potential design challenges. IR drop risk scores may be computed based on factors such as power switch density and cell clustering patterns within high-activity regions. Hold-time violation removal risk scores may indicate the difficulty of resolving timing violations based on available space for buffer insertion and/or inverter insertion. Static and dynamic power risk scores may flag regions with potentially excessive power consumption. Routing congestion risk scores may identify areas where routing resources may be insufficient.

A third component of the scoring result may include runtime prediction estimates generated using machine learning models as described in connection with FIG. 6. The runtime predictions estimate the expected turnaround time for completing subsequent design stages or the full RTL-to-GDSII flow based on the current design characteristics and parameter settings.

The scoring result computed at step 706 may be utilized in various ways. The scores may inform manual design decisions, enabling designers to identify problematic regions or parameter settings that should be revised. The scores may be incorporated into automated optimization frameworks such as the reinforcement learning system illustrated in FIG. 5, where they contribute to the reward signal that guides iterative parameter exploration. The scores may be aggregated across multiple modules to generate design-level (or block-level) quality metrics. Threshold-based filtering may flag modules or circuit blocks/designs that exceed acceptable risk levels for specific quality metrics.

In some embodiments, method 700 may be performed iteratively with different combinations of design flow parameter settings and physical design parameter settings to explore the design space and identify configurations that yield improved quality metrics. The iterative execution may be controlled manually by designers or automatically by an AI, ML, or RL agent as described in connection with FIG. 5. Through systematic exploration and evaluation using the scoring results, optimal or near-optimal design configurations can be identified that balance competing objectives such as performance, power consumption, area utilization, and design cycle time.

The method 700 illustrated in FIG. 7 provides a systematic approach to physical-aware logic synthesis that integrates physical design considerations during synthesis, generates comprehensive quality metrics through scoring, and enables data-driven design optimization to address challenges of designing integrated circuits at advanced semiconductor process nodes.

The terminology employed in the description of the various embodiments herein is intended for the purpose of describing particular embodiments and should not be construed as limiting. In the context of this description and the appended claims, the singular forms “a”, “an”, and “the” are intended to encompass plural forms as well, unless the context clearly indicates otherwise.

It should be understood that the term “and/or” as used herein is intended to encompass any and all possible combinations of one or more of the associated listed items. Furthermore, it should be noted that the terms “includes,” “including,” “comprises,” and/or “comprising,” when used in this specification, indicate the presence of stated features, integers, steps, operations, elements, and/or components, but do not exclude the presence or addition of one or more other features, integers, steps, operations, elements, components, and/or groups thereof.

Unless specifically stated otherwise, the term “some” refers to one or more. Various combinations using “at least one of” or “one or more of” followed by a list (e.g., A, B, or C) should be interpreted to include any combination of the listed items, including individual items and multiple items.

In the context of this disclosure, the terms “coupled,” “connected,” “connecting,” “electrically connected,” and similar expressions are used interchangeably to broadly denote the state of being electrically or electronically connected. Furthermore, an entity is deemed to be in “communication” with another entity (or entities) when it electrically transmits and/or receives information signals to/from the other entity, irrespective of whether these signals contain image/voice information or data/control information, and regardless of the signal type (analog or digital). It is important to note that this communication can occur through either wired or wireless means. The use of these terms is intended to encompass all forms of electrical or electronic connectivity relevant to the described embodiments.

The use of ordinal designators like “first,” “second,” and so forth in the specification and claims serves to differentiate between multiple instances of similarly named elements. These designators do not imply any inherent sequence, priority, or chronological order in the manufacturing process or functional relationship between elements. Rather, they are employed solely as a means of uniquely identifying and distinguishing between separate instances of elements that share a common name or description.

The directional terms used in the embodiments such as up, down, left, right, upper-side, down-side, in front of or behind are just the directions referring to the attached figures. Thus, the direction terms used in the present disclosure are for illustration, and are not intended to limit the scope of the present disclosure. It should be noted that the elements which are specifically described or labeled may exist in various forms for those skilled in the art.

As may be used throughout this specification and the appended claims, terms of approximation and degree such as “substantially,” “approximately,” “generally,” “essentially,” “nearly,” “about,” and similar expressions are used to account for variations in precision, manufacturing tolerances, measurement accuracy, environmental conditions, and inherent material properties that may affect the described features or characteristics. Such variations may range from ±20% in broader applications to progressively tighter tolerances of ±10%, ±5%, ±3%, ±2%, ±1%, or ±0.5% in more precise implementations. The specific degree of variation encompassed by these terms of approximation in any given context is informed by the nature of the component, relationship, or parameter being described, the technical requirements of the particular embodiment, and the understanding of one skilled in the relevant art.

The various illustrative components, logic, logical blocks, modules, circuits, operations and algorithm processes described in connection with the embodiments disclosed herein may be implemented as electronic hardware, firmware, software, or combinations of hardware, firmware or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

The hardware and data processing apparatus utilized to implement the various illustrative components, logics, logical blocks, modules, and circuits described herein may comprise, without limitation, one or more of the following: a general-purpose single-chip or multi-chip processor, a digital signal processor (DSP), an application specific integrated circuit (ASIC), a field programmable gate array (FPGA), other programmable logic devices (PLDs), discrete gate or transistor logic, discrete hardware components, or any suitable combination thereof. Such hardware and apparatus shall be configured to perform the functions described herein.

A general-purpose processor may include, but is not limited to, a microprocessor, or alternatively, any conventional processor, controller, microcontroller, or state machine. In certain implementations, a processor may be realized as a combination of computing devices. Such combinations may include, for example, a DSP and a microprocessor, a plurality of microprocessors, one or more microprocessors in conjunction with a DSP core, or any other such configuration as may be suitable for the intended application.

It is to be understood that in some embodiments, particular processes, operations, or methods may be executed by circuitry specifically designed for a given function. Such function-specific circuitry may be optimized to enhance performance, efficiency, or other relevant metrics for the particular task at hand. The selection of specific hardware implementation shall be determined based on the particular requirements of the application, which may include, inter alia, performance specifications, power consumption constraints, cost considerations, and size limitations.

In certain aspects, the subject matter described herein may be implemented as software. Specifically, various functions of the disclosed components, or steps of the methods, operations, processes, or algorithms described herein, may be realized as one or more modules within one or more computer programs. These computer programs may comprise non-transitory processor-executable or computer-executable instructions, encoded on one or more tangible processor-readable or computer-readable storage media. Such instructions are configured for execution by, or to control the operation of, data processing apparatus, including the components of the devices described herein. The aforementioned storage media may include, but are not limited to, Random Access Memory (RAM), Read Only Memory (ROM), Electrically Erasable Programmable Read-Only Memory (EEPROM), Compact Disc Read-Only Memory (CD-ROM) or other optical disk storage, magnetic disk storage or other magnetic storage devices, or any other medium capable of storing program code in the form of instructions or data structures. It should be understood that combinations of the above-mentioned storage media are also contemplated within the scope of computer-readable storage media for the purposes of this disclosure.

Some embodiments may involve computers on a distributed computing network, such as a network with multiple clients and/or servers. In such embodiments, clients may run software implementing client-side portions of the described systems and methods, while servers handle requests from these clients. Communication between clients and servers may occur via one or more electronic networks, which may include the Internet, wide area networks, mobile telephone networks, wireless networks (e.g., Wi-Fi, 5G), or local area networks, implemented using any known network protocols.

Various modifications to the embodiments described in this disclosure may be readily apparent to persons having ordinary skill in the art, and the generic principles defined herein may be applied to other embodiments without departing from the spirit or scope of this disclosure. Thus, the claims are not intended to be limited to the embodiments shown herein, but are to be accorded the widest scope consistent with this disclosure, the principles and the novel features disclosed herein.

In certain implementations, the embodiments may comprise the disclosed features and may optionally include additional features not explicitly described herein. Conversely, alternative implementations may be characterized by the substantial or complete absence of non-disclosed elements. For the avoidance of doubt, it should be understood that in some embodiments, non-disclosed elements may be intentionally omitted, either partially or entirely, without departing from the scope of the invention. Such omissions of non-disclosed elements shall not be construed as limiting the breadth of the claimed subject matter, provided that the explicitly disclosed features are present in the embodiment.

Additionally, various features that are described in this specification in the context of separate embodiments also can be implemented in combination in a single implementation. Conversely, various features that are described in the context of a single implementation also can be implemented in multiple embodiments separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

The depiction of operations in a particular sequence in the drawings should not be construed as a requirement for strict adherence to that order in practice, nor should it imply that all illustrated operations must be performed to achieve the desired results. The schematic flow diagrams may represent example processes, but it should be understood that additional, unillustrated operations may be incorporated at various points within the depicted sequence. Such additional operations may occur before, after, simultaneously with, or between any of the illustrated operations.

Additionally, it should be understood that the various figures and component diagrams presented and discussed within this document are provided for illustrative purposes only and are not drawn to scale. These visual representations are intended to facilitate understanding of the described embodiments and should not be construed as precise technical drawings or limiting the scope of the invention to the specific arrangements depicted.

In certain implementations, multitasking and parallel processing may prove advantageous. Furthermore, while various system components are described as separate entities in some embodiments, this separation should not be interpreted as mandatory for all embodiments. It is contemplated that the described program components and systems may be integrated into a single software package or distributed across multiple software packages, as dictated by the specific implementation requirements.

It should be noted that other embodiments, beyond those explicitly described, fall within the scope of the appended claims. The actions specified in the claims may, in some instances, be performed in an order different from that in which they are presented, while still achieving the desired outcomes. This flexibility in execution order is an inherent aspect of the claimed processes and should be considered within the scope of the invention.

While the invention has been described in connection with certain embodiments, it will be understood by those skilled in the art that various modifications and adaptations can be made without departing from the scope of the invention. The specific embodiments presented are intended to illustrate the invention and not to limit its application or construction. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A computer-implemented method for performing physical-aware logic synthesis, comprising:
receiving, by a synthesis environment, a register-transfer level (RTL) design and associated design constraints, one or more design flow parameter settings, and one or more physical design parameter settings;
synthesizing the RTL design into a gate-level netlist based on the design flow parameter settings and physical design parameter settings; and
computing a scoring result based on a logic synthesis result including the synthesized gate-level netlist, wherein the scoring result represents a quantitative measure of design quality.

2. The method of claim 1, wherein the design flow parameter settings comprise electronic design automation (EDA) tool and flow configurations.

3. The method of claim 1, wherein the physical design parameter settings comprise at least one of a standard cell utilization rate, aspect ratio, rectilinear shape specification, feed-through net information, channel dimensions, macro grouping definitions, macro guide constraints, power domain boundaries, power/ground grid density, and/or port placement guide specifications.

4. The method of claim 1, wherein, the scoring result comprises scattering metrics that evaluate placement density of standard cell instances within modules of the RTL design or the entire design/block.

5. The method of claim 4, wherein the scattering metric is computed as a ratio of an average Euclidean distance of standard cell instances from an average coordinate center of a module to a reference radius derived from a total cell area of the module.

6. The method of claim 5, wherein the average coordinate center is determined according to an average of all x-coordinates and y-coordinates of standard cell instances in the module.

7. The method of claim 5, wherein the scattering metric is computed for a plurality of modules in the RTL design, and the scoring result comprises a ranking of the modules according to their scattering metrics.

8. The method of claim 1, wherein synthesizing the RTL design comprises performing circuit block macro placement based on the physical design parameter settings.

9. The method of claim 8, wherein the physical design parameter settings are selected from the group consisting of: a standard cell utilization rate, an aspect ratio, a rectilinear shape specification, feed-through net numbers and locations, channel dimensions between macros, macro grouping definitions, macro guide constraints, power domain boundaries, a power-ground grid density, and port placement guide specifications.

10. The method of claim 1, further comprising computing PPA (power, performance and area) results and EDA tool runtime prediction results based on the logic synthesis result (which includes a gate-level netlist).

11. The method of claim 1, wherein an artificial intelligence (AI), reinforcement learning (RL), or machine learning (ML) agent iteratively adjusts the design flow parameter settings and the physical design parameter settings based on the computed scoring result.

12. A system for performing physical-aware logic synthesis, comprising:
a memory configured to store instructions; and
a processor, when executing the instructions, configured to:
receive a register-transfer level (RTL) design and associated design constraints, one or more design flow parameter settings, and one or more physical design parameter settings;
synthesize the RTL design into a gate-level netlist based on the design flow parameter settings and the physical design parameter settings; and
compute a scoring result based on a logic synthesis result including the synthesized gate-level netlist, wherein the scoring result represents a quantitative measure of design quality.

13. The system of claim 12, wherein the design flow parameter settings comprise electronic design automation (EDA) tool and flow configurations.

14. The system of claim 12, wherein the physical design parameter settings comprise at least one of a standard cell utilization rate, aspect ratio, feed-through net information, power/ground grid density rectilinear shape specification, channel dimensions, macro grouping definitions, macro guide constraints, power domain boundaries, and/or port placement guide specifications.

15. The method of claim 12, wherein the processor is further configured to perform circuit block macro placement based on the physical design parameter settings.

16. The system of claim 12, wherein the scoring result comprises scattering metrics that evaluate placement density of standard cell instances within modules of the RTL design or the entire circuit design/block.

17. The system of claim 16, wherein the scattering metric is computed as a ratio of an average Euclidean distance of standard cell instances from an average coordinate center of a module to a reference radius derived from a total cell area of the module.

18. The system of claim 17, wherein the scattering metric is computed for a plurality of modules in the RTL design, and the scoring result comprises a ranking of the modules according to their scattering metrics.

19. The system of claim 12, wherein the processor is further configured to compute, based on the gate-level netlist, power, performance, and area (PPA) results and EDA tool runtime prediction results.

20. The system of claim 12, wherein the instructions further cause the device to iteratively adjust the design flow parameter settings and the physical design parameter settings using an artificial intelligence (AI), reinforcement learning (RL), or machine learning (ML) agent based on the computed scoring result.
